(19) United States
(12) Patent Application Publication
(10) Pub. No.: US 2006/0252173 A1
(43) Pub. Date: Nov. 9, 2006

(54) Method for manufacturing photoelectric package having control chip

(76) Inventors: Bily Wang, Hsin Chu City (TW); John Lin, Min Hsiung Hsiang (TW); Shih-Yu Wu, Pan Chiao City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/416,161

(22) Filed: May 3, 2006

(30) Foreign Application Priority Data
May 6, 2005 (TW) 94114761

(51) Int. Cl. H01L 21/00

(52) U.S. Cl. 438/48

(57) ABSTRACT

A manufacturing method for a photoelectric package structure having a control chip is proposed. The photoelectric package structure concentrates light emitted therefrom, prevents external light interference and can be applied for advertising signs and backlight modules. Using the present invention increases the defect-free ratio and production quality. Applying the present invention for packaging light-emitting diode (LED) or optical sensor chips allows the necessary light-emitting requirements of electronic chips to be easily met. The package structure of the present invention is superior to conventional ones and the installation of the control chip doesn't reduce the light-emitting intensity. The major innovation of the present invention is disposing a photoelectric chip (or multiple photoelectric chips) on a control chip and then installing the control chip upon a substrate. Thus, installation-of the components is more convenient. Furthermore, an external frame or optical gratings can also be included to prevent external light interference.

### BACKGROUND OF THE INVENTION

1. Field of the Invention

The present invention is related to a method for manufacturing a photoelectric package structure having a control chip. The photoelectric package structure includes a semiconductor and an illuminant. It is convenient for chips' installation and prevents external light interference. In the present invention, a photoelectric chip is disposed above the control chip and installed on a substrate thereby so that the problem of light-emitting obstruction can be removed. In addition, an external frame is provided to prevent external light interference. Hence, the photoelectric package structure provided in the present invention is superior to conventional ones.

2. Description of Related Art

In the packaging industry, the semiconductor packaging industry is one of the most important. However, since electronic products are required to be light, thin, short, small and multifunctional, the light-emitting diode (LED) and optical sensor packaging industries have also grown rapidly. The LED and optical sensor packaging industries have become almost as important as the semiconductor package industry. The LED or semiconductor package industry unceasingly provides new techniques, such as the ball grid array (BGA) for photoelectric chip array packaging that meets the requirements of surface mount technology (SMT). Especially, a superior substrate is needed when the number of pins is larger. Meanwhile, the brightness of packaged products is also very important.

As is known to all, electronic packaging technology is about a manufacturing process that is used to install semiconductor integrated circuits (ICs) or LEDs together with other electronic components into an electrical connecting frame to form an electronic product and thereby provide a specific function. Electronic packaging has four main purposes: power distribution, signal distribution, heat dissipation and the provision of protection and support. Electronic packaging that is most often seen is IC chip packaging and LED packaging.

Reference is made to FIG. 1, which shows a conventional photoelectric packaging structure having a control chip. A substrate 30a is attached with a photoelectric chip 20a and a control chip 10a. The photoelectric chip 20a and the control chip 10a are connected to the internal circuit of the substrate 30a. An external package structure is then provided to encapsulate the chips and the substrate 30a. The conventional photoelectric package structure can be use to encapsulate multiple photoelectric chips.

However, in accordance with the conventional photoelectric package structure, attaching the photoelectric chip 20a and the control chip 10a to the substrate 30a is inconvenient. Furthermore, the handling of the materials is not easy either. It means that the photoelectric chip 20a and the control chip 10a should be disposed individually on the substrate 30a. The disposition procedure is complicated, needs to occupy a larger area, and has the possibility of reducing light-emitting efficiency. In practical applications, occupying a large area is an undesirable feature. Hence it is necessary to develop a package structure that is easy for chip disposition and reduces the occupied area.

Accordingly, for most of the LEDs on the market that need substrates, simple chip disposition procedure and size reduction are highly desirable in the packaging -process. Enhancement of light intensity and prevention of external light interference are also highly prized. The present invention is provided to meet these requirements.

### SUMMARY OF THE INVENTION

An objective of the present invention is to provide a photoelectric package structure having a control chip and a manufacturing method for the same. The present invention enhances light-emitting intensity, reduces overall size and is convenient for the installation of the components. The photoelectric package structure provided in the present invention can be applied for backlight modules, lamps, advertising signs or electromagnetic detectors. The present invention can be used to package illuminant components, such as LEDs, or optical sensors together with a substrate, has a low cost and produces packages of high quality.

For achieving the objectives above, in the present invention, a photoelectric chip is disposed above the control chip and thereby installed on a substrate. Furthermore, the present invention can be performed using the conventional packaging procedure and uncomplicated equipment.

The manufacturing method of the present invention includes providing a control chip and a photoelectric chip, which are combined to form an initial structure; combining the initial structure with a substrate to form a semi-finished package structure, wherein a surface of the control chip which is not being used for the chips' installation are combined with the substrate; and provide a package structure made of a transparent material for light transmission and disposed above the substrates to cover the photoelectric chip and the control chip. Therein the substrate has an internal circuit.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a conventional photoelectric package structure having a control chip;

FIG. 2 shows an initial structure of the present invention;

FIG. 3 shows a photoelectric package structure with a control chip in accordance with a preferred embodiment of the present invention;

FIG. 4 shows a photoelectric package structure with a control chip in accordance with another preferred embodiment of the present invention;

FIG. 5 shows a photoelectric package structure with a control chip in accordance with another preferred embodiment of the present invention; and

FIG. 6 is a flowchart showing the operative steps of the manufacturing method in accordance with the present invention.

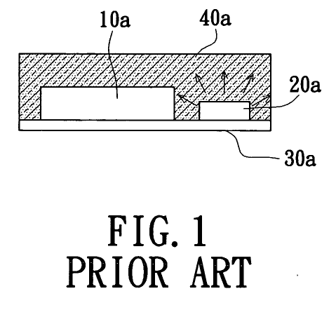

### DETAILED DESCRIPTION OF PREFERRED EMBODIMENTS

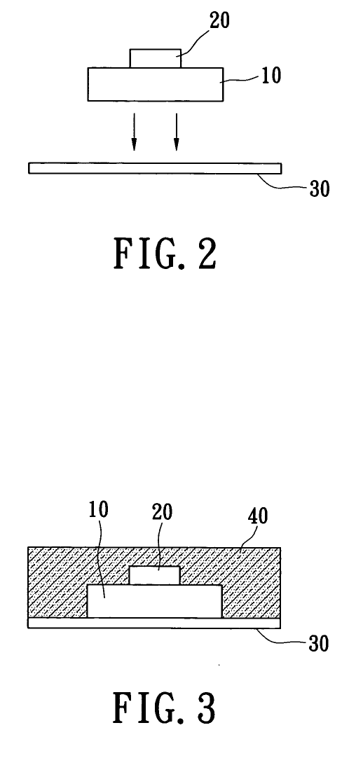

Reference is made to FIGS. 2-3, which show an embodiment of the present invention. The substrate 30 can have multiple layers. It has an upper surface and a lower surface. The upper surface is generally used for installation of a photoelectric chip 20. The photoelectric chip 20 can have LEDs or optical sensors. The substrate 10 has a circuit disposed therein. The photoelectric chip 20 is installed above the upper surface of the substrate 30 and connected to the control chip 10. The control chip 10 is disposed below the photoelectric chip 20 and connected to the upper surface of the substrate 30.

As shown in FIGS. 2-3, the photoelectric chip 20 and the control chip 10 are first combined together. The photoelectric chip 20 and the control chip 10 are then disposed on the upper surface of the substrate 30. The control chip 10 is connected to an internal circuit of the substrate 30.

The package structure 40 is made of a transparent material for light transmission and disposed above the substrate 30 to cover the photoelectric chip 20. In practice, the present invention can have multiple photoelectric chips. Multiple contacts connecting to the internal circuit of the substrate 30 can be provided on one side or on multiple predetermined sides of the substrate 30. The contacts are used for attachment to a specific electronic device. The package structure 40 is transparent and can be made of a macromolecule material that is highly transmissive, such as resin. The main structure of the present invention is shown in FIG. 2 and FIG. 3.

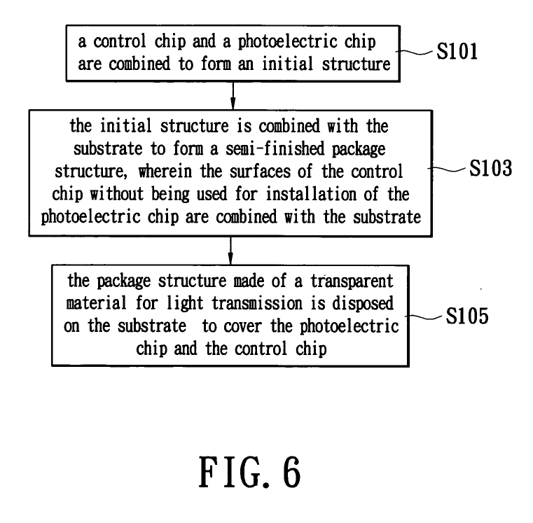

Reference is made to FIG. 6, which is a flowchart of a manufacturing method in accordance with the present invention. The manufacturing method includes the steps described below. A control chip 10 and a photoelectric chip 20 are provided and combined together to form an initial structure as shown in FIG. 2 (S101). The initial structure is then combined with the substrate 30 to form a semi-finished package structure as shown in FIG. 3 (S103). This means that the surfaces of the control chip 10, upon which the photoelectric chip 20 is not installed, are combined with the substrate 30 to form the semi-finished package structure. Finally, the package structure 40, made of a transparent material for light transmission, is disposed on the substrate 30 to cover the photoelectric chip 20 and the control chip 10. The substrate 30 has a circuit disposed inside (S105).

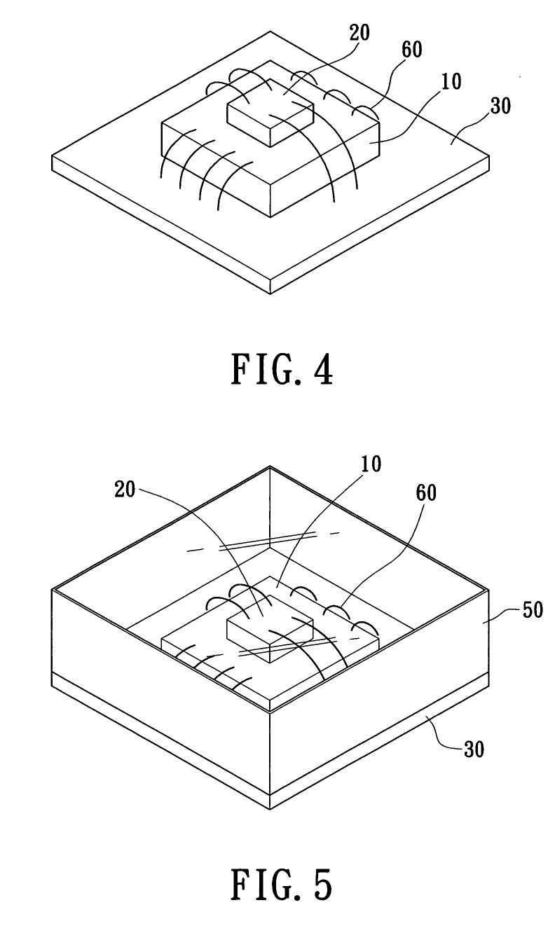

Reference is made to FIGS. 4 and 5. The embodiment of the present invention is accordingly detailed below. The substrate 30 can be multi-layered. The photoelectric chip 20 can have LEDs or optical sensors. The package structure 40 can be made of a macromolecule material. The package structure 40 can further have fluorescent powder distributed therein. The fluorescent powder can be green or yellow fluorescent powder or include a mixture of both.

The substrate 30 can be made of a copper circuit board. The package structure 40 can further have a reflective frame 50 surrounding thereof to prevent external light interference and reflect internal light upward. The package structure 40 can have a processed portion. The processed portion is formed with optical gratings or optical filter films for filtering or processing light. In practice, the present invention can be applied to package multiple photoelectric chips. The photoelectric chips can be arranged as an array or a totem, such as a trademark or an advertising sign. The light emitted from the photoelectric chips can be mixed to form white light. The present invention can further include multiple external contacts. The external contacts can be disposed on one side, multiple predetermined sides or upon the rear surface of the substrate 30 and connected to the internal circuit of the substrate 30. Furthermore, before installation of the package structure 40, the photoelectric chip 20 and the control chip 10 can be connected to the internal circuit of the substrate 30 via metal wires 60 as shown in FIG. 4. The photoelectric chip 20 and the control chip 10 can also be connected to the internal circuit of the substrate 30 via a metal eutectic structure.

The present invention has the following features: compared to the conventional package structure for packaging a control chip 10 and a photoelectric chip 20, the present invention changes the deposition of the control chip 10 to avoid obstructing light emitted from the photoelectric chip 20. It is also convenient for handling materials of electronic components and for assembly. External contacts can be disposed on one side, multiple predetermined sides or upon a rear surface of the rectangular substrate 30. A reflective frame 50, as shown in FIG. 5, or a processed portion, such as optical gratings or optical filter films for filtering or processing emitted light, can also be included. Thus, light-emitting intensity and component installation convenience for are improved. Furthermore, the cost is reduced and the conventional packaging procedure can be still used after slight modifications.

It should be noted that, in the present invention, the control chip 10 is disposed at a place to avoid obstructing light emitted from the photoelectric chip 20 and the mechanical equipment for this is cheap and easily obtained. Thus, the present invention is easy to realize. In addition, the substrate structure of the present invention is convenient for the installation of its components and enhances its light-emitting intensity. Furthermore, the conventional packaging procedure can be still applied for the present invention after slight modifications. This means that the conventional packaging procedure can still be used to manufacture the present invention after some of the conventional packaging machines are slightly modified. Thus, the present invention is practical.

The present invention has the following advantages:
(1) Installation of the manufacturing equipment is easy, and the cost of the equipment and techniques needed are not high;
(2) The control chip 10 is disposed at a place that avoids any obstruction of light emitted from the photoelectric chip 20 and thus reduces the overall size and makes the installation of the components more convenient;
(3) Most of conventional packaging machines are still usable; and
(4) Light-emitting intensity is enhanced and the conventional packaging procedure can still be used.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A manufacturing method for a photoelectric package structure having a control chip, comprising:
providing the control chip and a photoelectric chip, which are combined to form an initial structure;
combining the initial structure with a substrate to form a semi-finished package structure, wherein a surface of the control chip not being used for the chips' installation is combined with the substrate; and
providing, a package structure made of a transparent material for light transmission and disposed above the substrates to cover the photoelectric chip and the control chip;
wherein the substrate has an internal circuit.

2. The manufacturing method as claimed in claim 1, wherein the substrate has multiple layers.

3. The manufacturing method as claimed in claim 1, wherein the photoelectric chip is a light-emitting diode (LED) or an optical sensor.

4. The manufacturing method as claimed in claim 1, wherein the package structure is made of a macromolecule material.

5. The manufacturing method as claimed in claim 1, wherein the package structure further has a fluorescent powder distributed therein.

6. The manufacturing method as claimed in claim 5, wherein the fluorescent powder is a green or yellow fluorescent powder or includes a mixture of both.

7. The manufacturing method as claimed in claim 1, wherein the substrate is made of a copper circuit board.

8. The manufacturing method as claimed in claim 1, wherein the package structure further has a reflective frame surrounding thereof.

9. The manufacturing method as claimed in claim 1, wherein the package structure further has a processed portion.

10. The manufacturing method as claimed in claim 9, wherein the processed portion is formed with optical gratings or optical filter films.

11. The manufacturing method as claimed in claim 1, further comprising multiple photoelectric chips.

12. The manufacturing method as claimed in claim 11, wherein the photoelectric chips are arranged as an array or a totem.

13. The manufacturing method as claimed in claim 11, wherein lights emitted from the photoelectric chips are mixed to form a white light.

14. The manufacturing method as claimed in claim 11, wherein the substrate has external contacts, which connect to the internal circuit and are provided on one side, multiple predetermined sides or upon a rear surface of the substrate.

15. The manufacturing method as claimed in claim 1, further comprising:
connecting the control chip and the photoelectric chip to the internal circuit of the substrate via metal wires before the package structure is provided.

16. The manufacturing method as claimed in claim 1, wherein the control chip and the photoelectric chip are connected to the internal circuit of the substrate via a metal eutectic structure.
